(19) United States
(12) Patent Application Publication
(10) Pub. No.: US 2025/0279335 A1
(43) Pub. Date: Sep. 4, 2025

(54) SEMICONDUCTOR MODULE AND POWER ELECTRONICS DEVICE

(71) Applicant: FUJI ELECTRIC CO., LTD., Kawasaki-shi (JP)

(72) Inventors: Shinichi MASUDA, Matsumoto-city (JP); Junya KAWABATA, Matsumoto-city (JP)

(73) Assignee: FUJI ELECTRIC CO., LTD., Kawasaki-shi (JP)

(21) Appl. No.: 19/041,659

(22) Filed: Jan. 30, 2025

(30) Foreign Application Priority Data
Feb. 29, 2024 (JP) 2024-029795

(51) Int. Cl. H01L 23/40; H01L 23/055; H01L 23/538; H01L 25/07

(52) U.S. Cl. CPC H01L 23/4006; H01L 23/5385; H01L 25/072; H01L 23/055

(57) ABSTRACT

A semiconductor module includes insulated circuit boards and a heat dissipation base having a rectangular top surface on which the plurality of insulated circuit boards is disposed, and having four fastener holes that penetrate through the heat dissipation base in a thickness direction at respective ones of corners of the top surface. The heat dissipation base further includes a pair of fixing portions each having a fixing hole penetrating therethrough in the thickness direction. The pair of fixing portions protruding, in a plan view of the semiconductor module, outwardly respectively from central parts of a pair of first edges of the top surface. The pair of first edges oppose each other and extend in a longer-side direction of the top surface.

### CROSS-REFERENCE TO RELATED APPLICATION

This application is based upon and claims the benefit of priority of the prior Japanese Patent Application No. 2024-029795, filed on Feb. 29, 2024, the entire contents of which are incorporated herein by reference.

### BACKGROUND OF THE INVENTION

### 1. Field of the Invention

The embodiments discussed herein relate to a semiconductor module and a power electronics device.

### 2. Background of the Related Art

A semiconductor module includes semiconductor chips (power devices), insulated circuit boards on which the semiconductor chips are disposed, and a heat dissipation plate on which the multiple insulated circuit boards are disposed (see, for example, the following patent references (1) to (8)). A plurality of such semiconductor modules may be attached in parallel to a heat dissipation base (see, for example, the following patent references (1), (2), (6), and (8)). In this case, the semiconductor modules are attached to the heat dissipation base via joining members (for example, thermal grease, solder, or adhesive materials) (see, for example, the following patent references (1) and (6)).
(1) Japanese Laid-open Patent Publication No. 2013-004880
(2) Japanese Laid-open Patent Publication No. 2004-319992
(3) Japanese Laid-open Patent Publication No. 2007-059902
(4) Japanese Laid-open Patent Publication No. H04-229502
(5) Japanese Laid-open Patent Publication No. 2012-043915
(6) Japanese Patent No. 7258269
(7) Japanese Laid-open Patent Publication No. 2023-085765
(8) International Publication Pamphlet No. WO 2013/145619

### SUMMARY OF THE INVENTION

According to an aspect, there is provided a semiconductor module including a plurality of insulated circuit boards; and a heat dissipation base having a rectangular top surface on which the plurality of insulated circuit boards is disposed, and having four fastener holes that penetrate through the heat dissipation base in a thickness direction at respective ones of corners of the top surface, wherein: the heat dissipation base further includes a pair of fixing portions each having a fixing hole penetrating therethrough in the thickness direction, the pair of fixing portions protruding, in a plan view of the semiconductor module, outwardly respectively from central parts of a pair of first edges of the top surface, which opposes each other and extends in a longer-side direction of the top surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor module according to a first embodiment;

FIG. 2 is a side view of the semiconductor module according to the first embodiment;

FIG. 3 is a cross-sectional side view of the semiconductor module according to the first embodiment;

FIG. 4 is a plan view of a heat dissipation base with insulated circuit boards disposed thereon, included in the semiconductor module of the first embodiment;

FIG. 5 is a side view of the semiconductor module attached to a cooling module according to the first embodiment;

FIG. 6 is a side view of a semiconductor module attached to a cooling module (at room temperature) according to a reference example;

FIG. 7 is a side view of the semiconductor module attached to the cooling module (at high temperature) according to the reference example;

FIG. 8 is a plan view of a power electronics device including the semiconductor modules of the first embodiment;

FIG. 9 is a plan view of a semiconductor module according to a second embodiment;

FIG. 10 is a plan view of a semiconductor module according to a third embodiment; and

FIG. 11 is a plan view of a power electronics device including the semiconductor modules of the third embodiment.

### DETAILED DESCRIPTION OF THE INVENTION

Several embodiments will be described below with reference to the accompanying drawings. In the following, the terms “front surface” and “top surface” refer to the X-Y plane facing upward (in the +Z direction) in semiconductor modules and power electronics devices of the drawings. Similarly, the term “upper” refers to the upward direction (the +Z direction) of the illustrated semiconductor modules and power electronics devices. On the other hand, the terms “back surface” and “bottom surface” refer to the X-Y plane facing downward (in the-Z direction) in the illustrated semiconductor modules and power electronics devices. Similarly, the term “lower” refers to the downward direction (the −Z direction) of the illustrated semiconductor modules and power electronics devices. These terms have the same orientational relationships as described above in all the drawings if needed. The terms “front surface”, “top surface”, “upper”, “back surface”, “bottom surface”, “lower”, and “lateral surface” are simply expedient expressions used to specify relative positional relationships, and are not intended to limit the technical ideas of the embodiments described herein. For example, the terms “upper” and “lower” do not necessarily imply the vertical direction to the ground surface. That is, the “upper” and “lower” directions are not defined in relation to the direction of the gravitational force. In addition, the term “major component” in the following refers to a constituent having a concentration equal to 80 vol % or higher.

### (a) First Embodiment

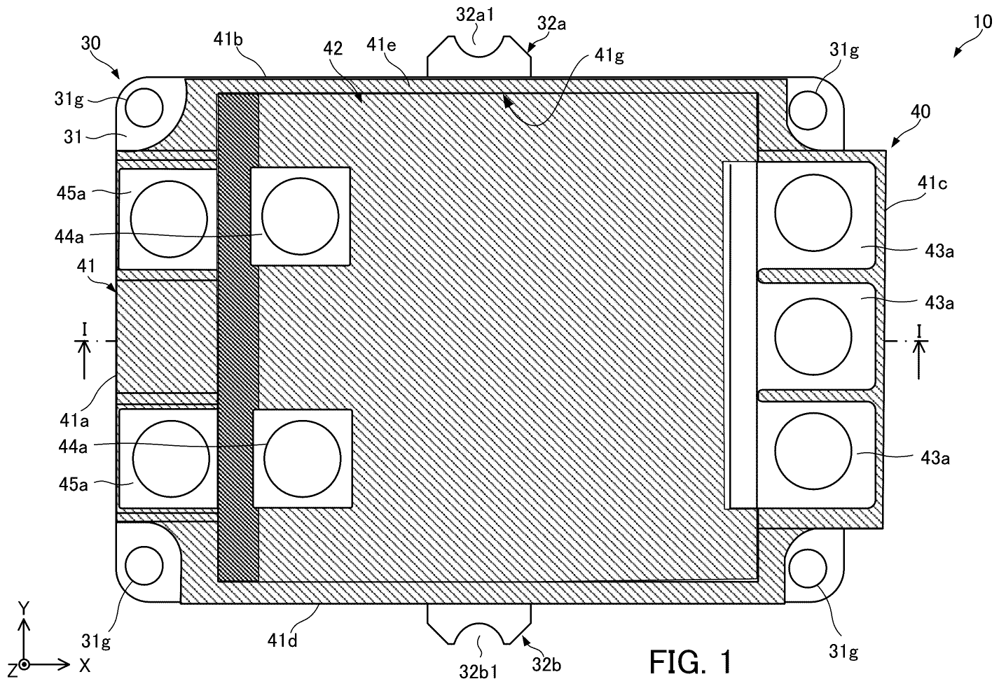

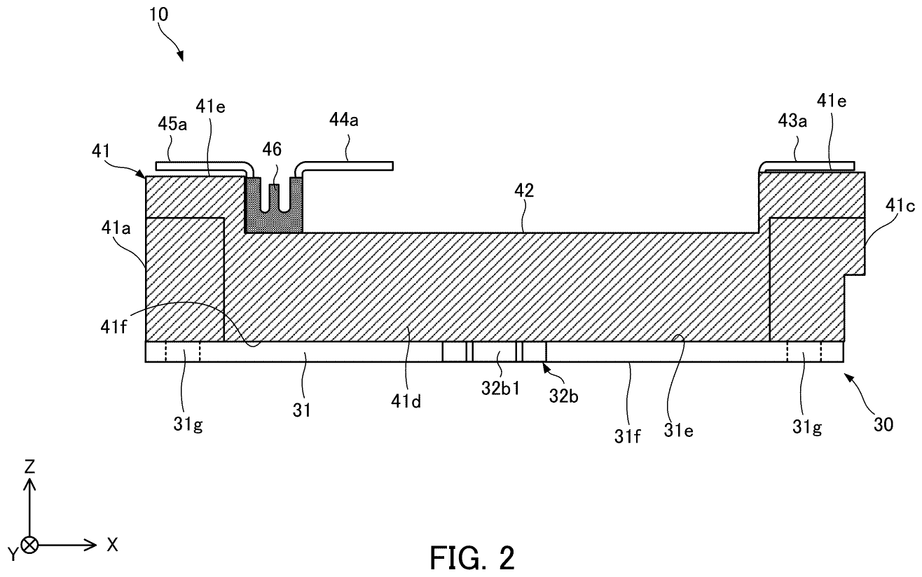

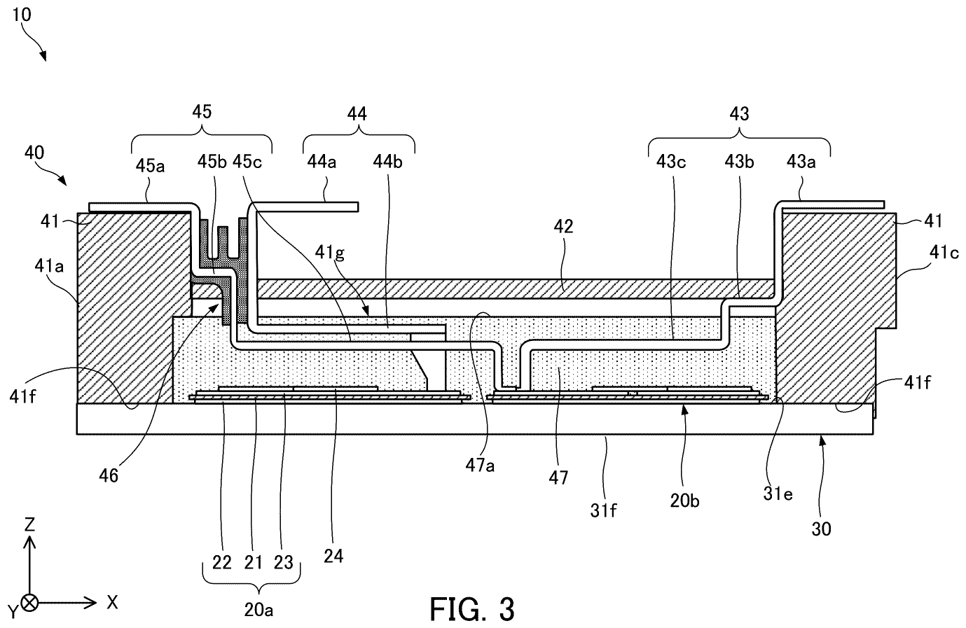

A semiconductor module 10 according to a first embodiment is described with reference to FIGS. 1 to 3. FIG. 1 is a plan view of a semiconductor module according to the first embodiment. FIG. 2 is a side view of the semiconductor module according to the first embodiment. FIG. 3 is a cross-sectional side view of the semiconductor module according to the first embodiment. The cross-sectional side view of FIG. 3 is taken along dash-dotted line I-I in FIG. 1. Note that FIG. 3 omits the illustration of wires.

The semiconductor module 10 includes a heat

dissipation base 30 disposed on the back surface and a case 40 disposed on the heat dissipation base 30 and covering the sides of the heat dissipation base 30. The semiconductor module 10 includes components housed in a housing area 41g surrounded by the heat dissipation base 30 and the case 40, and the components in the housing area 41g are sealed with a sealing member 47. The components included in the housing area 41g are, for example, insulated circuit boards, semiconductor chips disposed on the insulated circuit boards, and wires connecting these. FIG. 3 depicts insulated circuit boards 20a and 20b, as part of the insulated circuit boards, and semiconductor chips 24. The semiconductor module 10 includes external connection terminals 43 to 45.

The heat dissipation base 30 is a plate-shaped member in plan view. The outer shape of the heat dissipation base 30 may correspond to the outer shape of the case 40, except for fixing portions 32a and 32b to be described later. The heat dissipation base 30 may have R- or C-chamfered corners. The heat dissipation base 30 is made of a metal having excellent heat dissipation properties. Such a metal is, for example, copper, aluminum, or an alloy containing at least one of these. Plating may be applied to coat the surfaces of the heat dissipation base 30 in order to provide improved corrosion resistance. In this case, a material used for plating is, for example, nickel, a nickel-phosphorus alloy, or a nickel-boron Details of the heat dissipation base 30 will be alloy. described later.

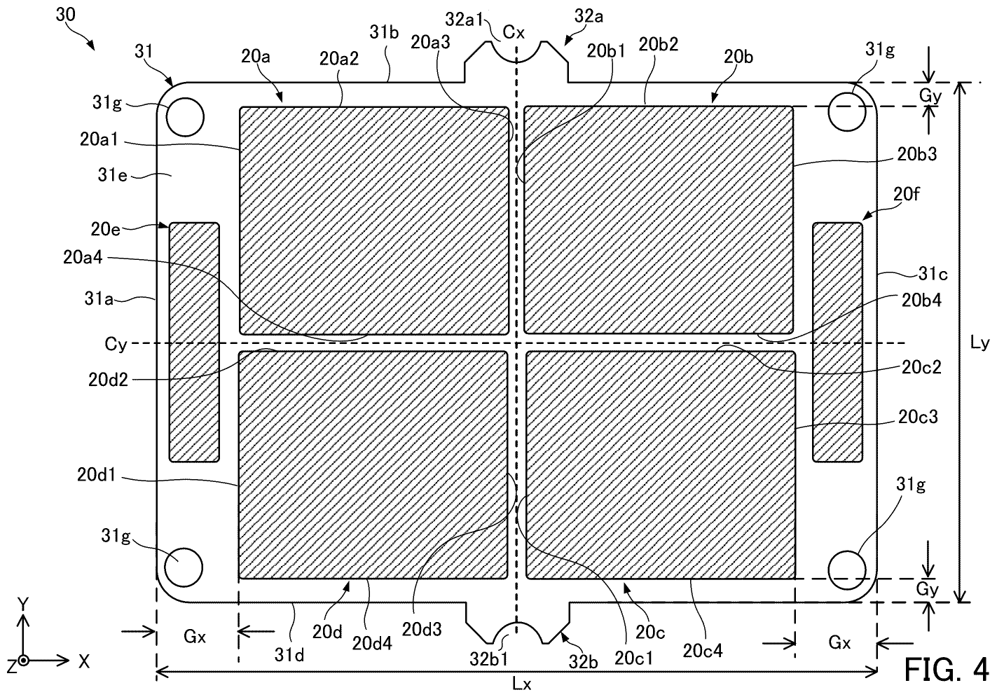

To the top surface of the heat dissipation base 30, insulated circuit boards 20a to 20d and insulated circuit boards 20e and 20f (see FIG. 4) are joined via joining members (not illustrated). The semiconductor chips 24 are joined to the insulated circuit boards 20a to 20d via joining members. Note that the insulated circuit boards 20a to 20d each include an insulating plate 21, a metal plate 22 disposed on the back surface of the insulating plate 21, and a conductive circuit pattern 23 disposed on the front surface of the insulating plate 21. The insulated circuit boards 20e and 20f (secondary insulated circuit boards) are similarly configured.

The joining members are, for example, solder. The solder used is lead-free solder. The lead-free solder contains, as a major component, at least one alloy selected from a tin-silver-copper alloy, a tin-zinc-bismuth alloy, a tin-copper alloy, and a tin-silver-indium-bismuth alloy, for example. Further, the solder may include an additive, such as nickel, germanium, cobalt, antimony, or silicon. The inclusion of the additive increases wettability, brightness, and bond strength of the solder, which results in improved reliability. The joining members may be sintered compacts instead of solder. The material of the sintered compacts used in joining is, for example, a powder of silver, iron, copper, aluminum, titanium, nickel, tungsten, or molybdenum.

The insulating plates 21 are each rectangular in plan view. The insulating plates 21 may have R-or C-chamfered corners. The insulating plates 21 are made of ceramic with excellent thermal conductivity. The ceramic here is made of a material containing, for example, aluminum oxide, silicon nitride, or aluminum nitride as a major component.

The metal plates 22 are made of a metal having excellent thermal conductivity as a major component. Such a metal is, for example, copper, aluminum, or an alloy containing at least one of these. Plating may be applied to coat the surfaces of the metal plates 22 in order to provide improved corrosion resistance. In this case, a material used for plating is, for example, nickel, a nickel-phosphorus alloy, or a nickel-boron alloy.

The conductive circuit patterns 23 are made of a material with excellent electrical conductivity. Such a metal is, for example, copper, aluminum, or an alloy containing at least one of these. Plating may be applied to the surfaces of the conductive circuit patterns 23 to provide improved corrosion resistance. In this case, a material used for plating is, for example, nickel, a nickel-phosphorus alloy, or a nickel-boron alloy. In addition, the semiconductor chips 24 and the external connection terminals 43 to 45 are mechanically and electrically connected to the conductive circuit patterns The conductive circuit patterns 23 may 23 as appropriate. each have a shape to realize a desired circuit, and may also be provided in plurality.

As the insulated circuit boards 20a to 20f having the aforementioned components, for example, direct copper bonding (DCB) boards or active metal brazed (AMB) boards may be used. The joining members described above may also be used to join the conductive circuit patterns 23 of the insulated circuit boards 20a to 20d and the semiconductor chips 24 and to join the conductive circuit patterns 23 of the insulated circuit boards 20a to 20d and the external connection terminals 43 to 45.

For the insulated circuit boards 20a to 20d on which the semiconductor chips 24 are mounted, wiring members may mechanically and electrically connect main electrodes of the semiconductor chips 24 to each other; the main electrodes of the semiconductor chips 24 and the conductive circuit patterns 23 to each other; and the multiple conductive circuit patterns 23 to each other. The wiring members are, for example, wires and lead frames made of a material having excellent electrical conductivity. The material is, for example, gold, silver, copper, aluminum, or an alloy containing at least one of these.

The semiconductor chips 24 may be power metal-oxide-semiconductor field-effect transistors (power MOSFETs) containing silicon carbide as a major component. In the power MOSFETs, body diodes may function as free wheeling diodes (FWDs). The semiconductor chips 24 each have an input electrode (drain electrode) functioning as a main electrode on the back surface, and an output electrode (source electrode) functioning as a main electrode and control electrodes (gate electrode) on the front surface. The control electrodes may be provided at the center of one side of the front surface of the individual semiconductor chips 24, or may be provided offset from the center along the side.

Alternatively, the semiconductor chips 24 may include a switching element containing silicon as a major component. The switching element is, for example, a reverse-conducting insulated gate bipolar transistor (RC-IGBT). The RC-IGBT is a semiconductor element having a single-chip structure with a circuit where an IGBT is connected antiparallel with a FWD. Each of the above semiconductor chips 24 has an input electrode (collector electrode) functioning as a main electrode on the back surface, and an output electrode (emitter electrode) functioning as a main electrode and control electrodes (gate electrode) on the front surface. The control electrodes may be provided at the center of one side of the front surface of each of the semiconductor chips 24, or may be provided offset from the center along the side, as in the case of the power MOSFETs described above.

Alternatively, the semiconductor chips 24 may be, for example, semiconductor chips containing silicon as a major component and each including a switching element or a diode element. Specifically, first semiconductor chips may be switching elements while second semiconductor chips may be diode elements. The switching elements are, for example, power MOSFETS or IGBTS. Each semiconductor chip including a switching element has, for example, an input electrode (a drain electrode in the case of a power MOSFET; and a collector electrode in the case of an IGBT)) functioning as a main electrode on the back surface, and a gate electrode functioning as control electrodes and an output electrode (a source electrode in the case of a power MOSFET; and an emitter electrode in the case of an IGBT) functioning as a main electrode on the front surface. As for the diode elements, for example, Schottky barrier diodes (SBD) or P-intrinsic-N (PiN) diodes are used as FWDs. Each semiconductor chip including a diode element has an output electrode (a cathode electrode) functioning as a main electrode on the back surface, and an input electrode (an anode electrode) functioning as a main electrode on the front surface.

The case 40 includes a frame portion 41, a lid portion 42 for covering the upper part of the frame portion 41, and the external connection terminals 43 to 45. The outer shape of the frame portion 41 is substantially rectangular in plan view and forms a frame shape. The frame portion 41 has the housing area 41g penetrating through the center. The frame portion 41 includes side walls 41a to 41d surrounding the housing area 41g on all four sides. The side walls 41a and 41c correspond to the shorter sides, and the side walls 41b and 41d correspond to the longer sides. A bottom surface 41f of the aforementioned frame portion 41 is joined to the outer edges of the top surface of the heat dissipation base 30 with adhesive or the like.

The external connection terminals 43 to 45 electrically connect the conductive circuit patterns 23 and an external device (not illustrated). The external connection terminals 43 to 45 are each formed of a flat plate-shaped conductive member. Part of the external connection terminals 44 and 45 is integrally held by a terminal holding portion 46.

One end of the external connection terminal 43 is exposed on a top surface 41e of the frame portion 41 of the case 40, and forms an external connection portion 43a for connection to the external device. The external connection terminal 43 also includes horizontal portions 43b and 43c formed in this order toward the other end from the external connection portion 43a. The horizontal portions 43b and 43c are parallel to the bottom surface of the housing area 41g. The height of the horizontal portion 43b is lower than that of the external connection portion 43a, and the height of the horizontal portion 43c is lower than that of the horizontal portion 43b. The external connection portion 43a and the horizontal portions 43b and 43c are formed, for example, by bending the flat plate-shaped external connection terminal 43. The external connection portion 43a and the horizontal portion 43b as well as the horizontal portion 43b and the horizontal portion 43c are connected by individual coupling portions extending vertically.

The external connection portion 43a is divided into three parts in the horizontal direction (the Y direction). A connection portion (no reference numeral given) extending downward is formed at the end of the horizontal portion 43c. The connection portion is electrically and mechanically connected to the respective conductive circuit patterns 23 of the insulated circuit boards 20b and 20c via solder. The connection here may be made directly by, for example, laser or ultrasonic welding.

One end of the external connection terminal 44 is exposed at the top of the lid portion 42 of the case 40, and forms an external connection portion 44a for connection to the external device (not illustrated). The external connection terminal 44 includes a horizontal portion 44b on the other end side as seen from the external connection portion 44a. The horizontal portion 44b is parallel to the bottom surface of the housing area 41g, and the height of the horizontal portion 44b is lower than that of the external connection portion 44a. The external connection portion 44a and the horizontal portion 44b are formed by bending the flat plate-shaped external connection terminal 44, and the external connection portion 44a and the horizontal portion 44b are connected by a coupling portion (no reference numeral given) extending vertically.

The external connection portion 44a is divided into two parts in the horizontal direction (the Y direction). Connection portions (no reference numerals given) extending downward are formed at the end of the horizontal portion 44b. The connection portions are electrically and mechanically connected to the respective conductive circuit patterns 23 of the insulated circuit boards 20a and 20d via solder. Alternatively, the connection here may be made directly by, for example, laser or ultrasonic welding.

One end of the external connection terminal 45 is exposed on the top surface 41e of the frame portion 41 of the case 40, and forms an external connection portion 45a for connection to the external device. The external connection terminal 45 also includes horizontal portions 45b and 45c formed in this order toward the other end from the external connection portion 45a. The horizontal portions 45b and 45c are parallel to the bottom surface of the housing area 41g. The height of the horizontal portion 45b is lower than that of the external connection portion 45a, and the height of the horizontal portion 45c is lower than that of the horizontal The external connection portion 45a and the portion 45b. horizontal portions 45b and 45c are formed, for example, by bending the flat plate-shaped external connection terminal 45. The external connection portion 45a and the horizontal portion 45b as well as the horizontal portion 45b and the horizontal portion 45c are connected by individual coupling portions (no reference numerals given) extending vertically.

The external connection portion 45a is divided into two parts in the horizontal direction (the Y direction). Connection portions (no reference numerals given) extending downward are formed at the end of the horizontal portion 45c. The connection portions are electrically and mechanically connected to the respective conductive circuit patterns 23 of the insulated circuit boards 20b and 20c via solder. Alternatively, the connection here may be made directly by, for example, laser or ultrasonic welding.

The terminal holding portion 46 seals the following portions together: the coupling portion connecting the external connection portion 44a and the horizontal portion 44b of the external connection terminal 44; the coupling portions of the external connection terminal 45, respectively connecting the external connection portion 45a and the horizontal portion 45b and connecting the horizontal portions 45b and 45c; and the horizontal portion 45b. This maintains insulation even when the external connection terminals 44 and 45 are disposed close to each other. The terminal holding portion 46 may be made of the same material as the case 40.

Although not illustrated in the drawings, control terminals may be provided. One ends of the control terminals are also exposed from the case 40 or the lid portion 42 of the case 40, and the other ends are disposed in the housing area 41g. The other ends of the control terminals are electrically connected to the control electrodes of the semiconductor chips 24 via the insulated circuit boards 20e and 20f. More specifically, the other ends of the control terminals are electrically and mechanically connected to conductive circuit patterns (not illustrated) of the insulated circuit boards 20e and 20f via solder. Alternatively, the control terminals may be directly connected by, for example, laser or ultrasonic welding. Note that the insulated circuit boards 20e and 20f may be mechanically and electrically connected to the control electrodes of the semiconductor chips 24 with control wires.

The horizontal portion 43c of the external connection terminal 43, the horizontal portion 44b of the external connection terminal 44, and the horizontal portion 45c of the external connection terminal 45 are disposed at positions lower than a top surface 47a of the sealing member 47 and are sealed with the sealing member 47. Note that the horizontal portion 44b of the external connection terminal 44 and the horizontal portion 45c of the external connection terminal 45 may be covered with a resin made of a different material from that of the sealing member 47. In this case, the top surface 47a of the sealing member 47 may be located lower than the horizontal portion 45c of the external connection terminal 45. In addition, the top surface 47a of the sealing member 47 may be located lower than the horizontal portion 43c of the external connection terminal 43.

The case 40 may be integrally formed by insert molding using a thermoplastic resin such that the frame portion 41 includes the external connection terminals 43 to 45. The lid portion 42 is also molded in a similar fashion. As such a thermoplastic resin, any of the following may be used: a polyphenylene sulfide resin; a polybutylene terephthalate resin; a polybutylene succinate resin; a polyamide resin; and an acrylonitrile butadiene styrene resin.

The housing area 41g surrounded by the heat dissipation base 30 and the frame portion 41 of the case 40 is filled with the sealing member 47. The insulated circuit boards 20a to 20f, the semiconductor chips 24, wiring members, and other components disposed in the housing area 41g are sealed with the sealing member 47. The sealing member 47 is an insulating polymer gel. The major component is preferably silicone gel.

Next, the heat dissipation base 30 where the insulated circuit boards 20a to 20f are disposed on a top surface 31e is described with reference to FIG. 4. FIG. 4 is a plan view of the heat dissipation base with the insulated circuit boards disposed thereon, which is included in the semiconductor module of the first embodiment. Note that the plan view of FIG. 4 depicts the heat dissipation base 30 with the insulated circuit boards 20a to 20e disposed thereon, excluding the case 40, the sealing member 47, the wires and the like from FIG. 1.

Also in FIG. 4, the insulated circuit boards 20a to 20f are represented in a simplified form. The insulated circuit boards 20a to 20d are rectangular in plan view, as described above. The insulated circuit boards 20a to 20d include lateral surfaces 20a1 to 20a4, 20b1 to 20b4, 20c1 to 20c4, and 20d1 to 20d4, respectively, that surround the four sides. The lateral surfaces 20a1, 20a3, 20b1, 20b3, 20c1, 20c3, 20d1, and 20d3 correspond to the shorter sides. On the other hand, the lateral surfaces 20a2, 20a4, 20b2, 20b4, 20c2, 20c4, 20d2, and 20d4 correspond to the longer sides.

The heat dissipation base 30 includes a heat dissipation plate 31 and the fixing portions 32a and 32b. Note that the heat dissipation plate 31 and the fixing portions 32a and 32b may be integrally connected, and may be made of the aforementioned metal as a major component. In addition, the heat dissipation base 30 may have a uniform thickness throughout, including the heat dissipation plate 31 and the fixing portions 32a and 32b. Alternatively, the thickness of the fixing portions 32a and 32b may be thinner than the thickness of the heat dissipation plate 31.

The heat dissipation plate 31 has a rectangular shape in plan view. The heat dissipation plate 31 includes the rectangular top surface 31e and a bottom surface 31f opposite the top surface 31e (see FIGS. 2 and 3). The heat dissipation plate 31 further includes lateral surfaces 31a to 31d surrounding the top surface 31e and the bottom surface 31f in order on all four sides. The lateral surfaces 31a and 31c correspond to second edges, and the lateral surfaces 31b and 31d correspond to first edges. The length of the lateral surfaces 31a and 31c (second edges) of the heat dissipation plate 31 is denoted by length Ly, and the length of the lateral surfaces 31b and 31d (first edges) is denoted by length Lx. The length Ly may be about 1.0 cm, and the length Lx may be about 1.4 cm.

The four corners of the heat dissipation plate 31 are individually formed where the lateral surfaces 31a and 31b meet, the lateral surfaces 31b and 31c meet, the lateral surfaces 31c and 31d meet, and the lateral surfaces 31d and 31a meet. These corners of the heat dissipation plate 31 may be R- or C-chamfered. The heat dissipation plate 31 has fastener holes 31g each provided at the four corners, penetrating the top surface 31e and the bottom surface 31f in the thickness direction (the ±Z direction). The four fastener holes 31g are individually located, on the top surface 31e of the heat dissipation plate 31, within a range of distance Gx (to be described later) from the lateral surfaces 31a and 31c and overlap a range of distance Gy (to be described later) from the lateral surfaces 31b and 31d.

Center lines Cx and Cy are set on the top surface 31e. The center line Cx is parallel to the lateral surfaces 31a and 31c (the paired second edges) and passes through the centers of the lateral surfaces 31b and 31d (the paired first edges). The center line Cy is parallel to the lateral surfaces 31b and 31d (the paired first edges) and passes through the centers of the lateral surfaces 31a and 31c (the paired second edges).

The insulated circuit boards 20a to 20f are disposed on the top surface 31e of the heat dissipation plate 31, as described above. The insulated circuit boards 20a to 20d are arranged in two rows and two columns on the top surface 31e of the heat dissipation plate 31, each separated by the center lines Cx and Cy.

The insulated circuit boards 20a and 20b are disposed such that the lateral surfaces 20a3 and 20b1 oppose each other at an equal distance across the center line Cx. The lateral surfaces 20a2 and 20b2 of the insulated circuit boards 20a and 20b are located outside (in the +Y direction) of a line connecting the centers of a pair of fastener holes 31g provided close to the lateral surface 31b of the heat dissipation plate 31. At this time, the shortest distance from the lateral surfaces 20a2 and 20b2 (first side) of the insulated circuit boards 20a and 20b to the lateral surface 31b of the heat dissipation plate 31 is the distance Gy. Note however that the paired fastener holes 31g formed closer to the lateral surface 31b of the heat dissipation plate 31 are located closer to the lateral surface 31b of the heat dissipation plate 31 than the lateral surfaces 20a2 and 20b2 of the insulated circuit boards 20a and 20b. That is, the lateral surfaces 20a2 and 20b2 of the insulated circuit boards 20a and 20b are located outside (in the +Y direction) of the line connecting the centers of the paired fastener holes 31g closer to the lateral surface 31b of the heat dissipation plate 31, but are not located outside (in the +Y direction) of the paired fastener holes 31g.

The insulated circuit boards 20d and 20c are disposed such that the lateral surfaces 20d3 and 20c1 oppose each other at an equal distance across the center line Cx. The lateral surfaces 20d4 and 20c4 of the insulated circuit boards 20d and 20c are located outside (in the −Y direction) of a line connecting the centers of a pair of fastener holes 31g provided close to the lateral surface 31d of the heat dissipation plate 31. At this time, the shortest distance from the lateral surfaces 20d4 and 20c4 (first side) of the insulated circuit boards 20d and 20c to the lateral surface 31d of the heat dissipation plate 31 is also the distance Gy. Note however that the paired fastener holes 31g formed closer to the lateral surface 31d of the heat dissipation plate 31 are located closer to the lateral surface 31d of the heat dissipation plate 31 than the lateral surfaces 20d4 and 20c4 of the insulated circuit boards 20d and 20c. That is, the lateral surfaces 20d4 and 20c4 of the insulated circuit boards 20d and 20c are located outside (in the −Y direction) of the line connecting the centers of the paired fastener holes 31g closer to the lateral surface 31d of the heat dissipation plate 31, but are not located outside (in the −Y direction) of the paired fastener holes 31g. The distance Gy of the insulated circuit boards 20a and 20b and the insulated circuit boards 20d and 20c to the lateral surfaces 31b and 31d of the heat dissipation base 30 may be, for example, 5% or more and 15% or less of the length Ly.

The insulated circuit boards 20a and 20d are disposed such that the lateral surfaces 20a4 and 20d2 oppose each other at an equal distance across the center line Cy. At this time, the shortest distance from the lateral surfaces 20a1 and 20d1 (second side) of the insulated circuit boards 20a and 20d to the lateral surface 31a of the heat dissipation plate 31 is the distance Gx. The insulated circuit boards 20b and 20c are disposed such that the lateral surfaces 20b4 and 20c2 oppose each other at an equal distance across the center line Cy. At this time, the shortest distance from the lateral surfaces 20b3 and 20c3 (second side) of the insulated circuit boards 20b and 20c to the lateral surface 31c of the heat dissipation plate 31 is the distance Gx. The distance Gx of the insulated circuit boards 20a and 20b and the insulated circuit boards 20d and 20c to the lateral surfaces 31a and 31c of the heat dissipation base 30 may be, for example, 15% or more and 20% or less of the length Lx.

Furthermore, the distance Gy of the insulated circuit boards 20a and 20b and the insulated circuit boards 20d and 20c to the lateral surfaces 31b and 31d of the heat dissipation base 30 is shorter than the distance Gx of the insulated circuit boards 20a and 20b and the insulated circuit boards 20d and 20c to the lateral surfaces 31a and 31c of the heat dissipation base 30. Note that the gaps between the respective insulated circuit boards 20a to 20d need only be large enough to maintain insulation.

The insulated circuit board 20e is provided between the fastener holes 31g on the lateral surface 31a side of the top surface 31e of the heat dissipation plate 31. The insulated circuit board 20f is provided between the fastener holes 31g on the lateral surface 31c side of the top surface 31e of the heat dissipation plate 31. The center line Cy passes through the centers of the insulated circuit boards 20e and 20f.

The fixing portions 32a and 32b are each provided in the central parts of the respective lateral surfaces 31b and 31d (the first edges) of the heat dissipation plate 31 in such a manner as to protrude outward. The first embodiment depicts the case where the fixing portions 32a and 32b are provided at the centers of the lateral surfaces 31b and 31d through which the center line Cx passes. The central parts of the lateral surfaces 31b and 31d need not necessarily be the centers of the lateral surfaces 31b and 31d through which the center line Cx passes, and may include a certain width. For example, the central parts may have a width of 30% or more and 70% or less of the length Lx.

Fixing holes 32a1 and 32b1 penetrate the fixing portions 32a and 32b in the thickness direction of the heat dissipation plate 31. Here, the fixing holes 32a1 and 32b1 each have a concave shape recessed toward the paired lateral surfaces 31b and 31d (the first edges). The shapes of the concave fixing holes 32a1 and 32b1 may be line-symmetric about the center line Cx. The shapes of the fixing holes 32a1 and 32b1 are not limited to being concave, and may be circular opening holes in plan view. In this case, the fixing holes 32a1 and 32b1 may also be line-symmetric about the center line Cx. In addition, the outer corners of the fixing portions 32a and 32b may be tapered.

That is, the heat dissipation base 30 integrally including the heat dissipation plate 31 and the fixing portions 32a and 32b includes the paired opposing lateral surfaces 31b and 31d (the first edges), which extend along the longer-side direction of the top surface 31e and the bottom surface 31f, and the paired opposing lateral surfaces 31a and 31c (the second edges), which extend along the shorter-side direction of the top surface 31e and the bottom surface 31f, and further includes the fixing portions 32a and 32b provided on the paired lateral surfaces 31b and 31d in such a manner as to protrude outward.

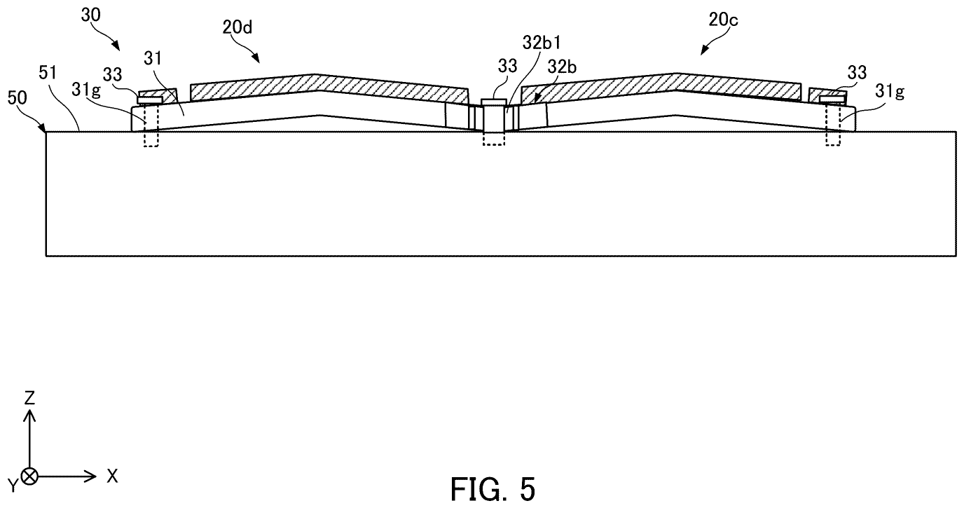

Next, attachment of the semiconductor module 10 including the above-described heat dissipation base 30 to a cooling module is described with reference to FIG. 5. FIG. 5 is a side view of the semiconductor module attached to a cooling module according to the first embodiment. Note that FIG. 5 omits the illustration of the case 40 of the semiconductor module 10 in FIG. 1 attached to a cooling module 50. Thus, FIG. 5 depicts a case where the heat dissipation base 30 with the insulated circuit boards 20a to 20d provided thereon is attached to the cooling module 50. The side view of FIG. 5 illustrates the semiconductor module 10 of FIG. 1 attached to the cooling module 50 as viewed in the +Y direction.

The cooling module 50 includes a top surface 51 on which the bottom surface 31f of the heat dissipation base 30 of the semiconductor module 10 is disposed. The top surface 51 is larger in area than the bottom surface 31f of the heat dissipation base 30 (including the fixing portions 32a and 32b), and is substantially flat. The cooling module 50 may be, for example, a heat radiator having heat dissipation fins or a cooling device where a refrigerant circulates the inside.

The heat dissipation base 30 of the semiconductor module 10 is disposed on the top surface 51 of the cooling module 50. Warping occurs in the heat dissipation base 30 due to thermal changes during the manufacturing process of the semiconductor module 10. Screws 33 (fixing members) inserted through the four fastener holes 31g and the fixing holes 32a1 and 32b1 (FIG. 5 depicts two fastener holes 31g and the fixing hole 32b1) are fastened (fixed) to the top surface 51 of the cooling module 50, and in this manner, the heat dissipation base 30 is attached to the top surface 51 of the cooling module 50.

The bottom surface 31f of the heat dissipation base 30 is disposed on the top surface 51 of the cooling module 50 via a joining member (not illustrated). The joining member may be, for example, a thermal interface material (hereinafter, TIM). Examples of the TIM include various materials, such as thermal conductive grease, an elastomer sheet, room temperature vulcanization (RTV) rubber, gel, and a phase change material.

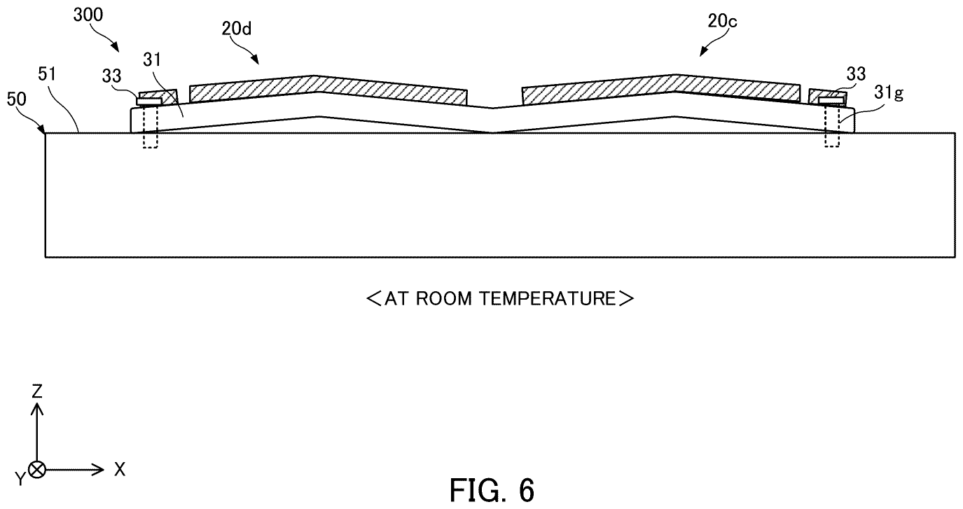

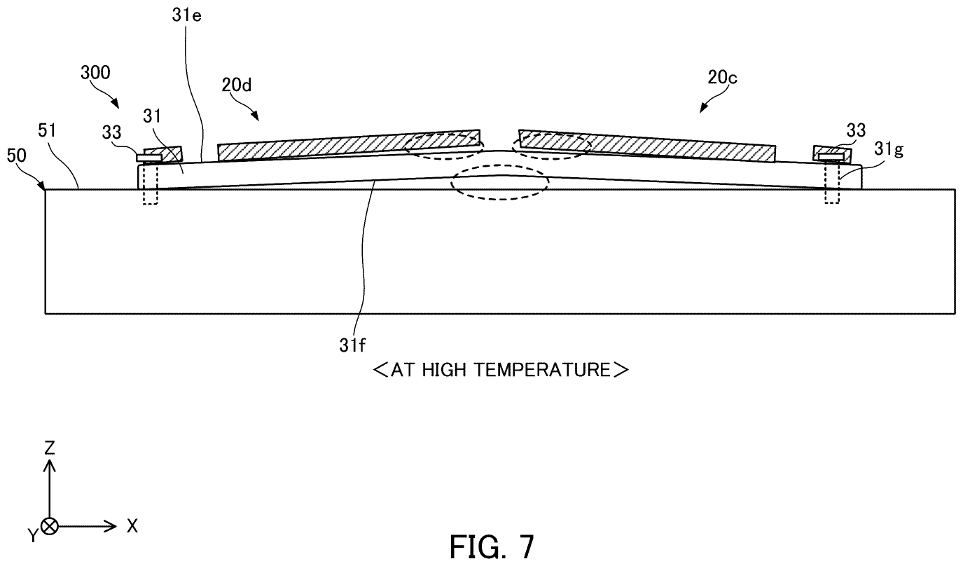

Here, a reference example is described in relation to the semiconductor module 10 (the heat dissipation base 30) of the first embodiment. A heat dissipation base 300 included in a semiconductor module of the reference example (not illustrated) is obtained by excluding the fixing portions 32a and 32b from the heat dissipation base 30 of the first embodiment. The semiconductor module 10 including the aforementioned heat dissipation base 300 and attached to the cooling module 50 is described with reference to FIGS. 6 and 7. FIG. 6 is a side view of the semiconductor module attached to the cooling module (at room temperature) according to the reference example. FIG. 7 is a side view of the semiconductor module attached to the cooling module (at high temperature) according to the reference example.

Note that FIGS. 6 and 7 correspond to FIG. 5, and illustrate the semiconductor module of the reference example as viewed in the +Y direction. FIGS. 6 and 7 also omit the illustration of the case 40. Therefore, FIGS. 6 and 7 represent the case where the heat dissipation base 300 with the insulated circuit boards 20a to 20f provided thereon is attached to the cooling module 50.

The heat dissipation base 300 of the semiconductor module of the reference example is also disposed on the top surface 51 of the cooling module 50 via a joining member (not illustrated). The heat dissipation base 300 is warped, as described above. The screws 33 inserted through the four fastener holes 31g (two fastener holes 31g are illustrated in FIGS. 6 and 7) are fastened to the top surface 51 of the cooling module 50, and the aforementioned heat dissipation base 300 is attached to the top surface 51 of the cooling module 50. In this manner, at room temperature when the semiconductor module of reference example is not in operation, the heat dissipation base 300 maintains the warpage immediately after the manufacture of the semiconductor module, as depicted in FIG. 6.

Next, the semiconductor module attached to the cooling module 50 represented in FIG. 6 is operated. The semiconductor module of the reference example generates heat in response to operation, and is then cooled by the cooling module 50. When the semiconductor module repeats such thermal changes, warping occurs in the heat dissipation base 300 (the heat dissipation plate 31).

In the heat dissipation base 300, the fastener holes 31g at the four corners are fixed to the top surface 51 of the cooling module 50. The heat dissipation base 300 warps upwardly, as illustrated in FIG. 7, also due to the difference in thermal expansion coefficient between the heat dissipation base 300 and the insulated circuit boards 20a to 20f. When the heat dissipation plate 31 warps upwardly, a gap is created between the bottom surface 31f of the heat dissipation plate 31 and the top surface 51 of the cooling module 50. As a result, the joining material flows out of the heat dissipation base 300 through the gap. This reduces the thermal conductivity of the heat dissipation base 300 to the cooling module 50.

Note that the insulated circuit boards 20a to 20d (FIG. 7 depicts only the insulated circuit boards 20d and 20c) are joined to the top surface 31e of the heat dissipation base 300. When the heat dissipation base 300 is warped upward, parts of the individual insulated circuit boards 20a to 20d, close to the central portion of the heat dissipation base 300 in plan view, are separated from the top surface 31e of the heat dissipation base 300. This reduces the thermal conductivity of the insulated circuit boards 20a to 20d to the heat dissipation base 300.

On the other hand, expansion of the heat dissipation base 300 may be considered to improve the heat dissipation performance. However, this hinders miniaturization of the semiconductor module. In particular, in the semiconductor module of the reference example, the insulated circuit boards 20a to 20f are arranged in a limited range on the top surface 31e of the heat dissipation base 300 without expanding the top surface 31e. The warping causes the semiconductor module of the reference example to lose heat dissipation performance, which makes the semiconductor module of the reference example more susceptible to failure and in turn reduces reliability.

On the other hand, the semiconductor module 10 of the first embodiment described above includes the multiple insulated circuit boards 20a to 20f and the heat dissipation base 30 including the top surface 31e on which the multiple insulated circuit boards 20a to 20f are disposed and having the fastener holes 31g each located at the corners of the top surface 31e and penetrating the heat dissipation base 30 in the thickness direction. The heat dissipation base 30 further includes the paired fixing portions 32a and 32b through which the fixing holes 32a1 and 32b1 penetrate in the thickness direction. The fixing portions 32a and 32b are provided in such a manner as to protrude, in plan view, outward relative to the paired opposing lateral surfaces 31b and 31d (the first edges) running along the longer-side direction of the top surface 31e from the central parts of the paired lateral surfaces 31b and 31d (the first edges). In the aforementioned semiconductor module 10, the fixing portions 32a and 32b of the paired lateral surfaces 31b and 31d (the first edges) are fixed to the top surface 51 of the cooling module 50, together with the fastener holes 31g at the four corners of the heat dissipation base 30. This suppresses the occurrence of upward convex warpage in the heat dissipation base 30. This also suppresses the outflow of the joining material from between the heat dissipation base 30 and the top surface 51 of the cooling module 50, which in turn suppresses detachment of the insulated circuit boards 20a to 20f from the heat dissipation base 30. As a result, a decrease in the heat dissipation of the semiconductor module 10 is suppressed, which thus suppresses degradation of the reliability of the semiconductor module 10.

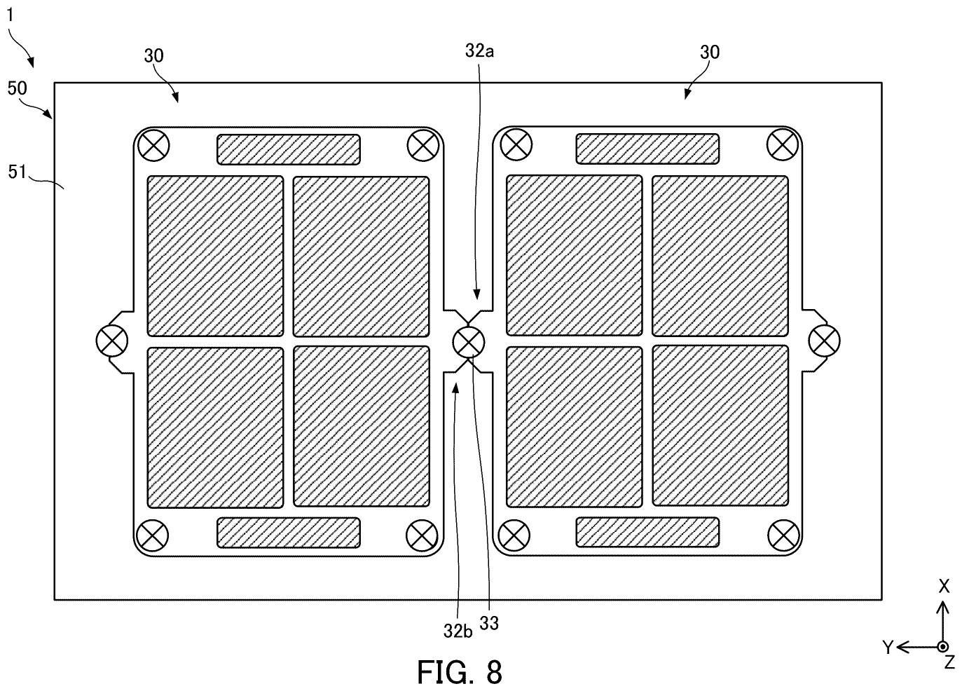

The above-described semiconductor module 10 may be provided in plurality and arranged in parallel to constitute a power electronics device. The power electronics device in this case is described with reference to FIG. 8. FIG. 8 is a plan view of the power electronics device including the semiconductor modules of the first embodiment. Note that FIG. 8 omits the illustration of the cases 40 of the semiconductor modules 10.

A power electronics device 1 includes two semiconductor modules 10 (heat dissipation bases 30) and the cooling module 50 on which the two semiconductor modules 10 are disposed. The two semiconductor modules 10 are adjacent to each other on the top surface 51 of the cooling module 50, and the respective lateral surfaces (the first edges) of the adjacent semiconductor modules 10 are arranged to oppose each other. In addition, the two semiconductor modules 10 are fastened to the top surface 51 of the cooling module 50 with the screws 33 inserted through the fastener holes 31g.

Furthermore, the two adjacent semiconductor modules 10 are fixed to the top surface 51 of the cooling module 50 with a common screw 33 inserted into an opening formed by combining the concave fixing hole 32a1 and the opposing concave fixing hole 32b1 provided on the respective first edges. The diameter of the opening corresponds to the diameter of the screw 33 inserted thereto.

Therefore, the inclusion of the fixing portions 32a and 32b in each semiconductor module 10 facilitates the connection of multiple semiconductor modules 10. When connecting the semiconductor modules 10, the opposing fixing portions 32a and 32b are aligned together, which allows the interval between the adjacent semiconductor modules 10 to be as narrow as possible.

Note that the shape of the fixing portions 32a and 32b is merely an example, and is not limited to the shape depicted in the first embodiment as long as the fixing holes 32a1 and 32b1 of the fixing portions 32a and 32b are aligned together to form an opening through which the screw 33 is inserted.

### (b) Second Embodiment

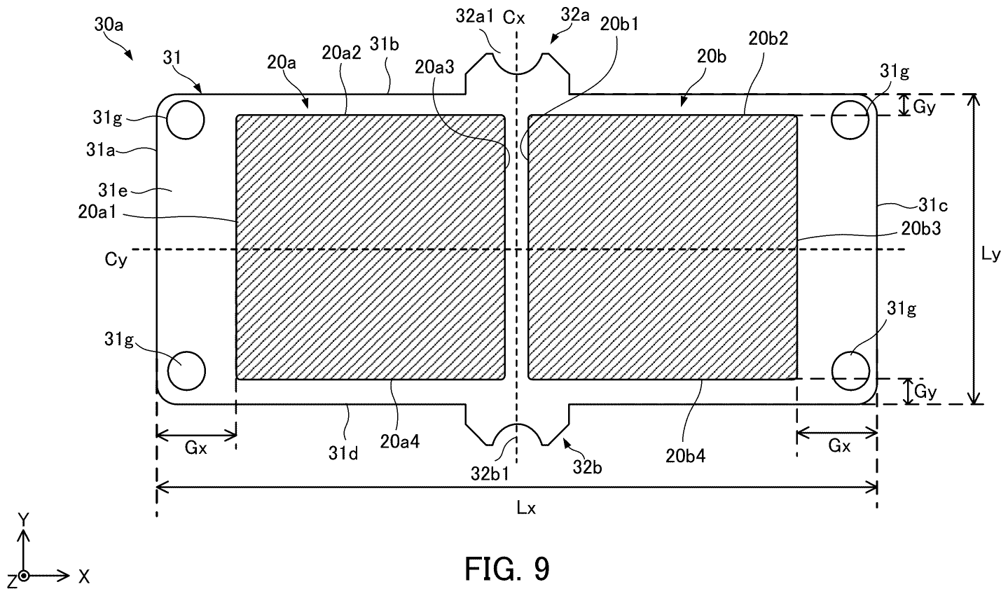

Next, a second embodiment describes a case where two insulated circuit boards are provided in the semiconductor module 10 of the first embodiment, with reference to FIG. 9. FIG. 9 is a plan view of a semiconductor module according to the second embodiment. A case depicted in FIG. 9 differs from FIG. 4 of the first embodiment in that only the insulated circuit boards 20a and 20b are provided, and the size of the heat dissipation base 30 is adjusted to match the insulated circuit boards 20a and 20b. Note that FIG. 9 omits the illustration of the insulated circuit boards 20e and 20f. In addition, the insulated circuit boards 20a and 20b are illustrated in a simplified manner. The insulated circuit boards 20a and 20b are rectangular in plan view, as described above.

A heat dissipation base 30a of the second embodiment also includes the heat dissipation plate 31 and the fixing portions 32a and 32b. Note that the heat dissipation plate 31 and the fixing portions 32a and 32b may be integrally connected to each other, and may be made of the aforementioned metal as the major component.

The heat dissipation plate 31 has a rectangular shape in plan view. The heat dissipation plate 31 includes the rectangular top surface 31e and the bottom surface 31f (not illustrated) opposite the top surface 31e. The heat dissipation plate 31 further includes the lateral surfaces 31a to 31d surrounding the top surface 31e and the bottom surface 31f in order on all four sides. The lateral surfaces 31a and 31c correspond to the second edges along the shorter-side direction while the lateral surfaces 31b and 31d correspond to the first edges along the longer-side direction. The length of the lateral surfaces 31a and 31c (the second edges) of the heat dissipation plate 31 is the length Ly, and the length of the lateral surfaces 31b and 31d (the first edges) is the length Lx. The length Ly may be about 0.5 cm, and the length Lx may be about 1.4 cm. Thus, the heat dissipation plate 31 of the second embodiment is different from the heat dissipation plate 31 of the first embodiment only in size, and has the same configuration. In addition, the center lines Cx and Cy are set in the same manner.

The fixing portions 32a and 32b also have the same shape and size as those in the first embodiment, have the fixing holes 32a1 and 32b1 provided therein, and are connected to the central parts of the lateral surfaces 31b and 31d of the heat dissipation plate 31 as in the first embodiment.

The: insulated circuit boards 20a and 20b are disposed such that the lateral surfaces 20a3 and 20b1 oppose each other at an equal distance across the center line Cx. The lateral surfaces 20a2 and 20b2 of the insulated circuit boards 20a and 20b are located outside (in the +Y direction) of a line connecting the centers of a pair of fastener holes 31g provided close to the lateral surface 31b of the heat dissipation plate 31. At this time, the shortest distance from the lateral surfaces 20a2 and 20b2 of the insulated circuit boards 20a and 20b to the lateral surface 31b of the heat dissipation plate 31 is the distance Gy. The lateral surfaces 20a4 and 20b4 of the insulated circuit boards 20a and 20b are located outside (in the −Y direction) of a line connecting the centers of a pair of fastener holes 31g provided close to the lateral surface 31d of the heat dissipation plate 31. At this time, the shortest distance from the lateral surfaces 20a4 and 20b4 of the insulated circuit boards 20a and 20b to the lateral surface 31d of the heat dissipation plate 31 is the distance Gy. The distance Gy of the insulated circuit boards 20a and 20b to the lateral surfaces 31b and 31d of the heat dissipation base 30a may be, for example, 5% or more and 15% or less of the length Ly, as in the first embodiment.

The insulated circuit boards 20a and 20b are arranged symmetrically with respect to the center line Cy. In this case, the shortest distance from the lateral surfaces 20a1 and 20b3 of the insulated circuit boards 20a and 20b to the lateral surfaces 31a and 31c of the heat dissipation plate 31 is the distance Gx. The distance Gx of the insulated circuit boards 20a and 20b to the lateral surfaces 31a and 31c of the heat dissipation base 30a may be, for example, 15% or more and 20% or less of the length Lx, as in the first embodiment. The distance Gy of the insulated circuit boards 20a and 20b to the lateral surfaces 31b and 31d of the heat dissipation base 30a is shorter than the distance Gx of the insulated circuit boards 20a and 20b to the lateral surfaces 31a and 31c of the heat dissipation base 30a.

The heat dissipation base 30a of the second embodiment also further includes the paired fixing portions 32a and 32b through which the fixing holes 32a1 and 32b1 penetrate in the thickness direction. The fixing portions 32a and 32b are provided in such a manner as to protrude, in plan view, outward relative to the paired opposing lateral surfaces 31b and 31d (the first edges) of the top surface 31e from the central parts of the paired lateral surfaces 31b and 31d (the first edges). In the aforementioned semiconductor module 10 of the second embodiment, the fixing portions 32a and 32b of the paired lateral surfaces 31b and 31d (the first edges) are also fixed to the top surface 51 of the cooling module 50, together with the fastener holes 31g at the four corners of the heat dissipation base 30a. This suppresses the occurrence of upward convex warpage in the heat dissipation base 30a. This also suppresses the outflow of the joining material from between the heat dissipation base 30a and the top surface 51 of the cooling module 50, which in turn suppresses detachment of the insulated circuit boards 20a and 20b from the heat dissipation base 30a. As a result, a decrease in the heat dissipation of the semiconductor module 10 is suppressed, which thus suppresses degradation of the reliability of the semiconductor module 10.

In addition, the semiconductor modules 10 (the heat dissipation base 30a) of the second embodiment may also be fixed to the top surface 51 of the cooling module 50 with a common screw 33 inserted into an opening formed by combining the fixing holes 32a1 and 32b1 of the fixing portions 32a and 32b opposing each other, as in FIG. 8.

### (c) Third Embodiment

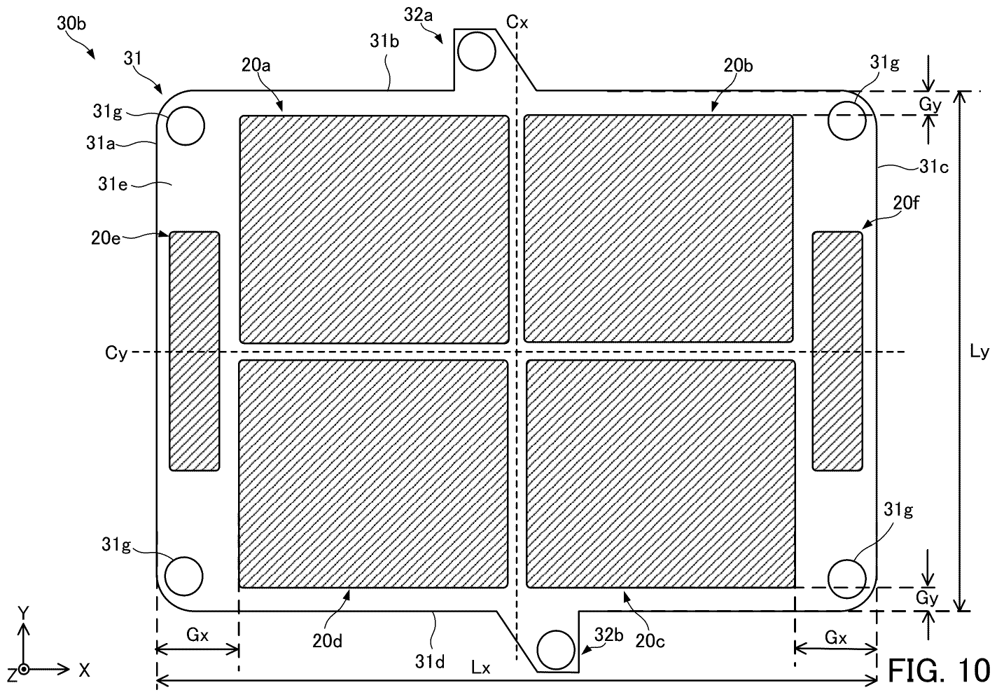

Next, a third embodiment describes a semiconductor module in which the fixing portions have a shape different from that of the first embodiment, with reference to FIG. 10. FIG. 10 is a plan view of the semiconductor module according to the third embodiment.

A heat dissipation base 30b may be made of the same material as the heat dissipation base 30 of the first embodiment, and includes the heat dissipation plate 31 and the fixing portions 32a and 32b. The heat dissipation plate 31 may be the same as in the first embodiment. In addition, the insulated circuit boards 20a to 20f are provided on the top surface 31e of the heat dissipation plate 31, as in the first embodiment.

The fixing portions 32a and 32b are each provided in the central parts of the respective lateral surfaces 31b and 31d (the first edges) of the heat dissipation plate 31 in such a manner as to protrude outward. The fixing portions 32a and 32b may be trapezoidal in plan view. In this case, one side of the trapezoid connecting the upper base and the lower base forms a right angle with the upper base and the lower base. Therefore, the fixing portions 32a and 32b are respectively shifted to the opposite sides to each other in a direction perpendicular to the center line Cx passing through the centers of the lateral surfaces 31b and 31d (the first edges). Furthermore, the fixing portions 32a and 32b are point-symmetric about the center point of the top surface 31e of the heat dissipation plate 31.

In addition, the fixing portions 32a and 32b have the fixing holes 32a1 and 32b1 each formed closer to the upper base, which is shorter than the lower base. Therefore, the fixing holes 32a1 and 32b1 are provided in the protruding parts of the fixing portions 32a and 32b, respectively, in such a manner that they are shifted in positions in opposite directions to each other about the center line Cx and are point-symmetric about the center point of the top surface 31e of the heat dissipation plate 31. In this way, the fixing portions 32a and 32b (the fixing holes 32a1 and 32b1) are not aligned straight on the center line Cx, but are provided within the above-mentioned ranges in the central parts of the lateral surfaces 31b and 31d.

In the semiconductor module of the third embodiment, the fixing portions 32a and 32b of the paired lateral surfaces 31b and 31d (the first edges) are also fixed to the top surface 51 of the cooling module 50, together with the fastener holes 31g at the four corners of the heat dissipation base 30b, as in the first embodiment. This suppresses the occurrence of upward convex warpage in the heat dissipation base 30b, as in the first embodiment. This also suppresses the outflow of the joining material from between the heat dissipation base 30b and the top surface 51 of the cooling module 50, which in turn suppresses detachment of the insulated circuit boards 20a to 20f from the heat dissipation base 30b. As a result, a decrease in the heat dissipation of the semiconductor module is suppressed, which thus suppresses degradation of the reliability of the semiconductor module.

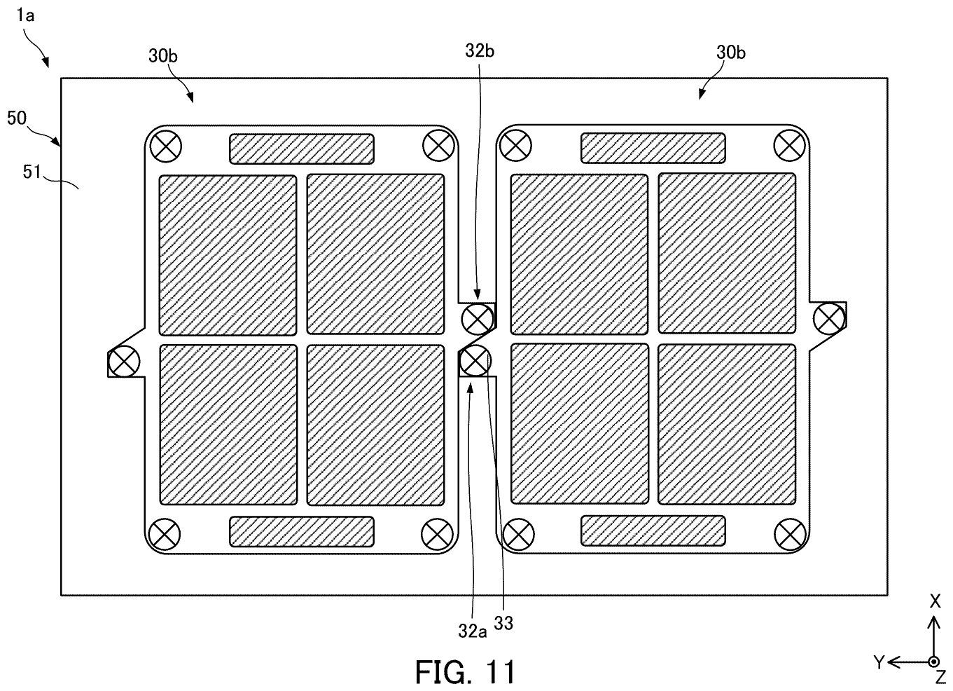

Also in the third embodiment, the above-described semiconductor module may be provided in plurality and arranged in parallel to constitute a power electronics device. The power electronics device in this case is described with reference to FIG. 11. FIG. 11 is a plan view of the power electronics device including the semiconductor modules of the third embodiment. Note that FIG. 11 omits the illustration of the cases 40 of the semiconductor modules.

A power electronics device 1 a includes two semiconductor modules (the heat dissipation bases 30b) and the cooling module 50 similar to that of the first embodiment on which the two semiconductor modules (the heat dissipation bases 30b) are disposed. The two semiconductor modules (the heat dissipation bases 30b) are adjacent to each other on the top surface 51 of the cooling module 50, and the respective lateral surfaces (the first edges) of the adjacent semiconductor modules (the heat dissipation bases 30b) are arranged to oppose each other. In addition, the two semiconductor modules (the heat dissipation bases 30b) are fastened to the top surface 51 of the cooling module 50 with the screws 33 inserted through the fastener holes 31g.

In addition, the two adjacent semiconductor modules (the heat dissipation bases 30b) are fixed to the top surface 51 of the cooling module 50 with the screws 33 inserted through the respective fixing holes 32a1 and 32b1 of the trapezoidal fixing portions 32a and 32b provided in the respective lateral surfaces (first edges) and fitting together in a staggered fashion.

Therefore, also in the case of the semiconductor module (the heat dissipation base 30b) of the third embodiment, the inclusion of the fixing portions 32a and 32b facilitates the connection of multiple semiconductor modules (the heat dissipation bases 30b). When connecting the semiconductor modules, the opposing fixing portions 32a and 32b are aligned each other, which allows the interval between the adjacent semiconductor modules (the heat dissipation bases 30b) to be as narrow as possible.

Note that the shape of the fixing portions 32a and 32b of the third embodiment is merely an example, and is not limited to the shape described in the third embodiment as long as the fixing holes 32a1 and 32b1 of the fixing portions 32a and 32b are aligned with each other when the semiconductor modules (the heat dissipation bases 30b) are disposed adjacent to each other.

According to an aspect, it is possible to reduce deformation of the heat dissipation bases due to thermal changes.

All examples and conditional language provided

herein are intended for the pedagogical purposes of aiding the reader in understanding the invention and the concepts contributed by the inventor to further the art, and are not to be construed as limitations to such specifically recited examples and conditions, nor does the organization of such examples in the specification relate to as of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor module, comprising:
a plurality of insulated circuit boards; and
a heat dissipation base having a rectangular top surface on which the plurality of insulated circuit boards is disposed, and having four fastener holes that penetrate through the heat dissipation base in a thickness direction at respective ones of corners of the top surface, wherein:
the heat dissipation base further includes a pair of fixing portions each having a fixing hole penetrating therethrough in the thickness direction, the pair of fixing portions protruding, in a plan view of the semiconductor module, outwardly respectively from central parts of a pair of first edges of the top surface, which oppose each other and extend in a longer-side direction of the top surface.

2. The semiconductor module according to claim 1, wherein:
a shortest distance from a closest insulated circuit board among the plurality of insulated circuit boards, that is closest to one first edge of the top surface to the one first edge is shorter than a shortest distance from a closest insulated circuit board among the plurality of insulated circuit boards, that is closest to one second edge of a pair of second edges of the top surface to the one second edge, the pair of second edges opposing each other and extending in a shorter-side direction of the top surface orthogonal to the longer-side direction.

3. The semiconductor module according to claim 2, further comprising
an other insulated circuit board smaller than each of the plurality of insulated circuit boards, on the top surface of the heat dissipation base at an area between the closest insulated circuit board and the one second edge that has the shortest distance.

4. The semiconductor module according to claim 2, wherein:
each of the plurality of insulated circuit boards has a pair of longer-sides extending in the longer-side direction and a pair of shorter-sides extending in the shorter-side direction,
the shortest distance between the closest insulated circuit board and the one first edge of the top surface is a distance between one longer-side of the closest insulated circuit board and the one first edge, and
the shortest distance between the closest insulated circuit board and the one second edge of the top surface is a distance between one shorter-side of the closest insulated circuit board and the one second edge.

5. The semiconductor module according to claim 4, wherein:
the plurality of insulated circuit boards is four insulated circuit boards, and are disposed on the top surface of the heat dissipation base in two rows and two columns across a center line passing through centers of the pair of first edges of the top surface and a center line passing through centers of the pair of second edges of the top surface.

6. The semiconductor module according to claim 4, wherein:
the plurality of insulated circuit boards is two insulated circuit boards, and are disposed on the top surface of the heat dissipation base across a center line passing through centers of the pair of first edges of the top surface.

7. The semiconductor module according to claim 1, wherein:
the fixing holes of the pair of fixing portions each have a concave shape recessed toward the pair of first edges in the plan view, respectively.

8. The semiconductor module according to claim 1, wherein:
the pair of fixing portions each protrudes in a direction away from the respective first edges and are offset from each other in opposite directions that are directions respectively away from a center line passing through centers of the pair of first edges in the plan view, and is point-symmetric about a center of the top surface of the heat dissipation base.

9. The semiconductor module according to claim 1, wherein:
the pair of fixing portions is integrally formed on the pair of first edges of the heat dissipation base.

10. The semiconductor module according to claim 9, wherein:
a thickness of the pair of fixing portions in the thickness direction is equal to or thinner than a thickness of the heat dissipation base.

11. The semiconductor module according to claim 1, wherein:
each of the fastener holes is provided closer to a corresponding edge of the heat dissipation base than is a corresponding one of the pair of first edges of the top surface of the heat dissipation base.

12. A power electronics device, comprising:
the semiconductor module of claim 7 provided in plurality; and
a cooling module including a top surface on which the plurality of semiconductor modules is disposed, each of the plurality of semiconductor modules being fixed to the top surface of the cooling module with a fixing member inserted through each of the fastener holes of the heat dissipation base thereof, wherein:
the plurality of semiconductor modules are disposed adjacent to each other such that one of the pair of first edges of the top surface of the heat dissipation base of one semiconductor module of an adjacent two semiconductor modules faces one of the pair of first edges of the top surface of the heat dissipation base of the other semiconductor module of the adjacent two semiconductor modules, so that the fixing hole of one of the pair of fixing portions of the one semiconductor module and the fixing hole of one of the pair of fixing portions of the other semiconductor modules penetrate therethrough in the thickness direction so that the adjacent two semiconductor modules are further fixed to the top surface of the cooling module with a fixing member inserted through the one fixing hole.

13. A power electronics device, comprising:
the semiconductor module of claim 8 provided in plurality; and
a cooling module including a top surface on which the plurality of semiconductor modules is disposed, each semiconductor module being fixed to the top surface of the cooling module with a fixing member inserted through each of the fastener holes of the heat dissipation base thereof, wherein:
the plurality of semiconductor modules are disposed adjacent to each other such that one of the pair of first edges of the top surface of the heat dissipation base of one semiconductor module of an adjacent two semiconductor modules faces one of the pair of first edges of the top surface of the heat dissipation base of the other semiconductor module of the adjacent two semiconductor modules, so that one of the pair of fixing portions of the one semiconductor module engages with one of the pair of fixing portions of the other semiconductor modules, the adjacent two semiconductor modules being further fixed to the top surface of the cooling module with a fixing member inserted through each of the fixing holes.
